(19) United States
(12) Patent Application Publication
(10) Pub. No.: US 2009/0002980 A1
(43) Pub. Date: Jan. 1, 2009

(54) Pixel Array and Tile for a Video Display

(76) Inventor: Robert Michael, Sydney (AU)

Correspondence Address: LACKENBACH SIEGEL, LLP, LACKENBACH SIEGEL BUILDING, 1 CHASE ROAD, SCARSDALE, NY, 10583, US

(21) Appl. No.: 12/094,852

(22) PCT Filed: Feb. 6, 2007
(86) PCT No.: PCT/AU2007/000113

§ 371 Date: Aug. 27, 2008

(30) Foreign Application Priority Data
Feb. 6, 2006 (AU) 2006900532

(51) Int. Cl. H01L 33/00

(52) U.S. Cl. 362/231; 438/27; 257/E33.067

(57) ABSTRACT

The invention provides a rectangular pixel array, a tile for a large display such as a video and a method for forming a rectangular array of pixels. The pixel array includes a reflector array having a reflector well for each pixel and a dice carrier including a plurality of dice for each pixel.

### TECHNICAL FIELD

This invention relates to pixels, in particular, this invention relates to pixel arrays.

### BACKGROUND ART

International patent application No WO 94/15434 (referred to below as the “International Application”) disclosed a pixel which included light emitting diodes (LEDs) embedded in a light scattering medium and associated with an optical barrier. When this prior art pixel was used to form an array, each pixel was separated from another by an optical barrier.

In an embodiment disclosed in the International Application, the LEDs were mounted to two separate lead frames. To assemble the pixel, jigging was required to hold a reflector for the pixel separately from the lead frame, with both having to be held in a fixed position during curing of the light scattering medium, such as an epoxy resin containing light scattering material.

In one mode of manufacture of the pixels disclosed in the International Application, the pixels which had been formed individually were mounted onto a printed circuit board. Each individual pixel had a multiple number of leads attached. This could lead to problems in mounting the pixels automatically. The costs associated with manual mounting were prohibitive.

Problems can be encountered in producing pixels individually and then assembling them into an array. The problem can be intensified by the fact that there is a desire to make pixels in a smaller form and to pitch them more closely together. As a result, in practical terms it is extremely difficult to handle pixels individually and to form them into an acceptable array. In prior art construction of pixels, it has been necessary to provide special tooling, such as a lead frame creation tool, a lead frame bending tool and a singulating tool.

It is an object of the present invention to avoid the requirement for this proprietary tooling.

### DISCLOSURE OF THE INVENTION

In the present invention, a different approach is taken to forming pixel arrays. With the present invention, a pixel array can be formed in two parts. A reflector array for the pixels in the array represents one part and a carrier for the dice, capable of locating the dice relative to the reflector array, represents the second part. Optionally, pegs may be included to allow precise positioning of pixel arrays to form a larger matrix.

Accordingly, this invention provides a pixel array which includes:
a) a reflector array having reflector means for each pixel; and
b) a dice carrier including a plurality of dice for each pixel.

The invention also provides a method for forming an array of pixels, the method including the steps of:
a) providing a reflector array;
b) locating relative to the reflector array a carrier having a plurality of dice; and
c) providing electrical connection to each die.

The pixel array of the invention may be of any suitable size. One such suitable size is an array of sixteen pixels, arranged in a 4×4 grid. This, in turn, can be used to construct tiles for the active matrix of a video display. If each tile consists of 1024 pixels in a 32×32 array, 64 pixel arrays of the invention in the 4×4 format would be required. It is to be understood that the scope of the present invention is not limited to pixel arrays of any particular size.

The invention also provides a tile or matrix containing a plurality of pixel arrays of the invention.

The pixel array of the invention may be used to form a tile in any suitable way. By way of example, each pixel array of the invention may be assembled on a printed circuit board for the tile, using solder balls for connection. This can eliminate the need for “through hole” connection in the tile printed circuit board, which in turn can contribute significantly to reliability of the tile and to that of the ultimate video display.

It will be appreciated by one skilled in the art that, because the pixel array of the invention may be connected to a printed circuit board carrier without handling individual pixels, pixel topology may be changed much more readily than in the case of the prior art, simply by reworking the printed circuit board. In this way, pixel design may be readily and inexpensively upgraded in accordance with developments in die (LED) performance.

For example, at one time the light output available from a blue die was very low. Consequently, a pixel would have one red, one green and two blue dice. Technology of blue dice matured and eventually a far greater degree of output was available. At this stage, it was possible to redesign a pixel so that it contained one red, one blue and two green dice. Since then, there have been further advances. The light output from a green die has increased greatly. While it would have been possible to construct a suitable pixel having only three dice, one red, one blue and one green, the lead frame use dictated that the change be instead to a four dice topology, namely one red, one blue, one green and one further green being an inexpensive low output die.

Whereas, in the case of the prior art, it would have required a major redesign to switch to a three die topology with the new green die technology, with the present invention such a change can be trivial and can result in a 25% reduction in component cost. Since a typical display may contain 327,000 pixels, a 25% reduction in component cost can be extremely significant.

Although at present for colour video displays, it is usually necessary to have at least four dice—one red, one blue and two green, it is anticipated that there may be developments in this regard in the future. The invention is not limited to any particular number of dice.

It is to be emphasised that the number of pixels in an array of the invention can be chosen from a wide range.

The reflector array has reflector means for each pixel. Each reflector means is preferably a reflector well forming the base of each pixel in the array. The reflector array and the reflector means are preferably made from polycarbonate by injection moulding.

The dice carrier may be of any suitable construction. In a preferred embodiment, the reflector array is constructed so as to resemble an egg carton, with a hole at the bottom of each reflector means. The reflector array can then be assembled over the dice carrier, with the dice located in the holes of the reflector means.

Once the pixel array of the invention has been formed, the light scattering medium (such as a translucent potting agent) may be applied to the assembly and cured as appropriate. The array may then be attached to a suitable printed circuit board, for example, using solder balls as mentioned above, to form tiles.

It is preferred that non-conductive pegs are located on the underside of the reflector array, more preferably one at each of the corners of the underside, to allow precise positioning of pixel arrays of the invention to form a larger matrix, such as a tile.

It will be appreciated by one skilled in the art that the pixel array of the invention can enable practical implementation of a large display matrix, using smaller pixels which can be set at a finer pitch than formerly. This is desirable, because minimum viewing distance of such a display matrix can be reduced and at the same time image quality can be greatly improved.

### BRIEF DESCRIPTION OF THE DRAWINGS

The invention will now be described in connection with a preferred embodiment as set out in the attached drawings. The embodiment is not limiting on the scope of the invention.

In the drawings:

FIG. 1 is a perspective view, partly broken away, of a pixel array according to the invention;

FIG. 2 is an enlarged view of one of the reflector means shown in FIG. 1, partly broken away as in FIG. 1;

FIG. 3 shows a full perspective view of the reflector means of FIG. 2;

FIG. 4 is a plan view of part of a dice carrier;

FIG. 5 is a top view of the reflector array, part of which is detailed in FIG. 1;

FIG. 6 is a sectional view of the array of FIG. 5, taken along the lines BB in FIG. 5;

FIG. 7 is a sectional view of the array of FIG. 5, taken along the lines AA of FIG. 5;

FIG. 8 is a bottom plan view of the reflector array of FIG. 5;

FIG. 9 is a plan view of the dice carrier according to the invention;

FIG. 10 is a side elevation of the dice carrier of FIG. 1; and

FIG. 11 is a plan view from below of the dice carrier of FIGS. 9 and 10, showing the location of solder balls.

### BEST MODE OF CARRYING OUT THE INVENTION

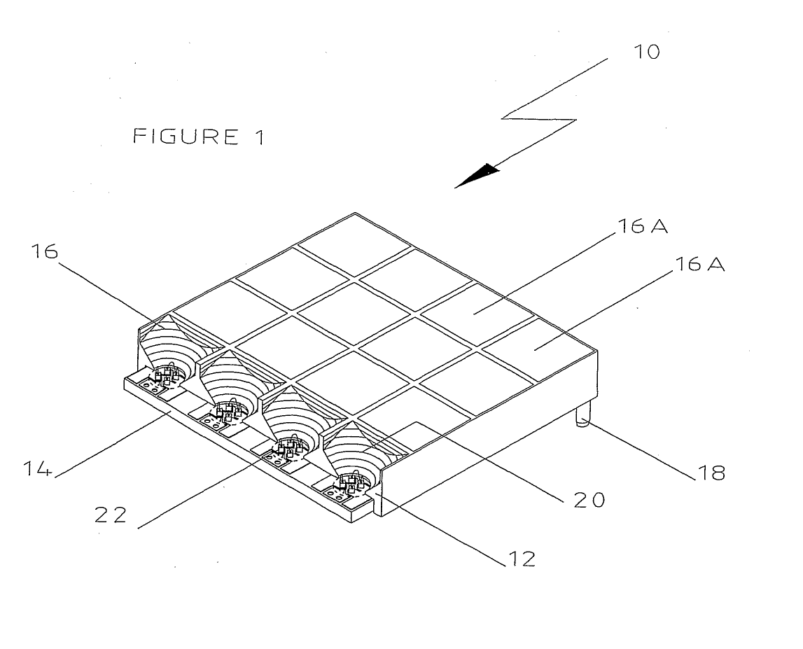

Turning first to FIG. 1, pixel array 10 is shown with reflector array 12 and dice carrier 14. Pixel array 10 has an array of 4×4 pixels 16, only four of which are shown in detail, in partly broken away form.

Pixel array 10 includes non-conductive peg 18. Although not shown, a similar peg is located at each of the other three corners of pixel array 10.

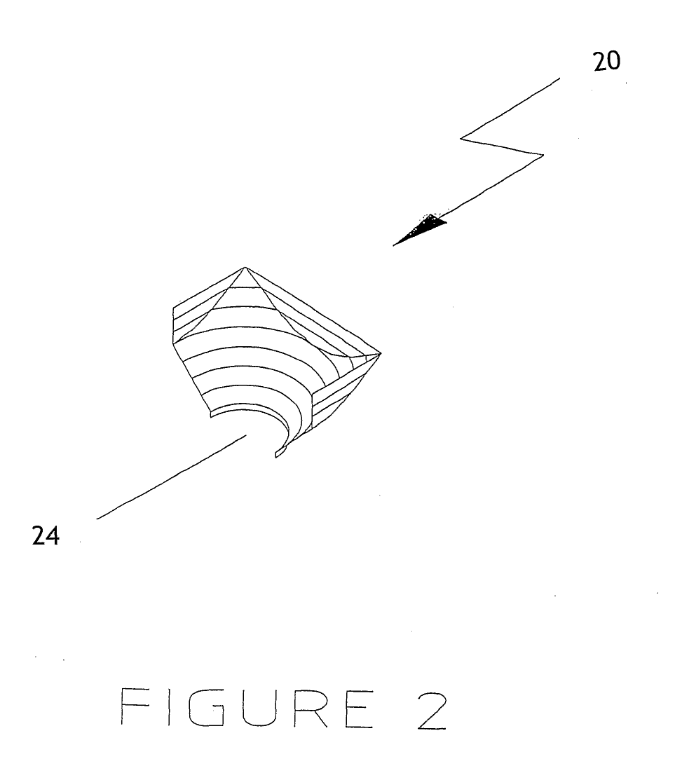

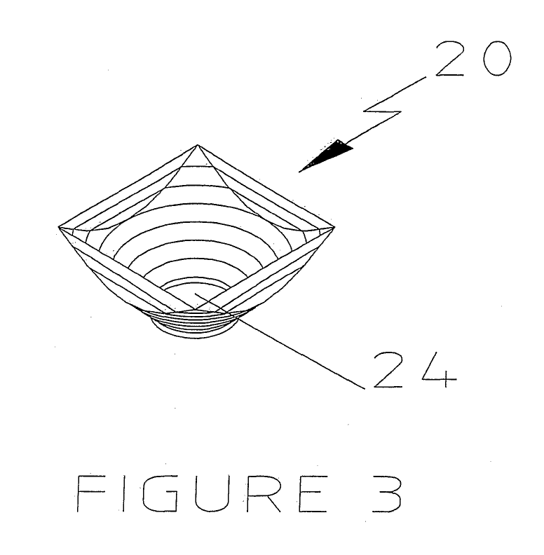

Reflector array 12 includes sixteen reflector means 20. These are discussed in further detail in connection with FIGS. 2 and 3.

Pixel array 10 also includes a set of dice for each pixel 16. In this embodiment, each set of dice has four dice, illustrated generally at 22. These may comprise one red die, one blue die and two green dice, or any other desirable combination. The invention is not limited to any particular number of dice, although for colour video displays it is usually necessary to have at least three dice—one red, one blue and one green.

As can be seen from FIG. 1, each set of dice 22 is situated on dice carrier 14 and located in hole 24 (see FIG. 2) located at the base of each reflector means 20.

Each reflector means 20 is filled with a suitable light scattering medium, such as a resin with appropriate light scattering material. The surface of each pixel 16 is substantially flat, as shown, for example, at 16a.

Turning now to FIGS. 2 and 3, reflector means 20 is made of suitable reflector material such as polycarbonate containing 10% titanium dioxide and, as illustrated, is based on concentric circles tapering towards hole 24 at the base of reflector means 20. As explained in relation to FIG. 1, above, a set of dice is intended to be located in hole 24. Reflector means 20 is filled with a translucent potting agent, as already discussed, to form a light pipe.

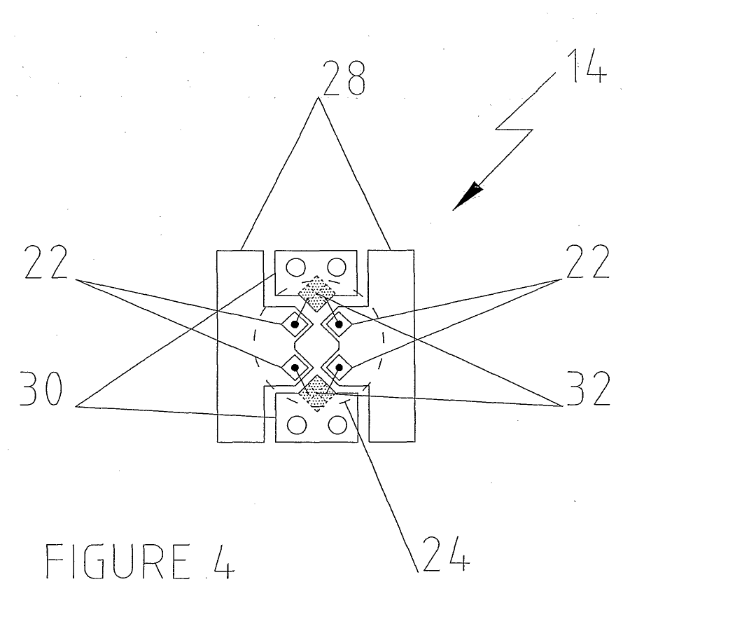

In FIG. 4, the border of hole 24 in reflector means 20 is indicated by a dashed line. Some of the dice 22 are labelled. Anode connections are indicated at 28, while cathode connections are indicated at 30. Each pair of dice is linked at wire bond area 32.

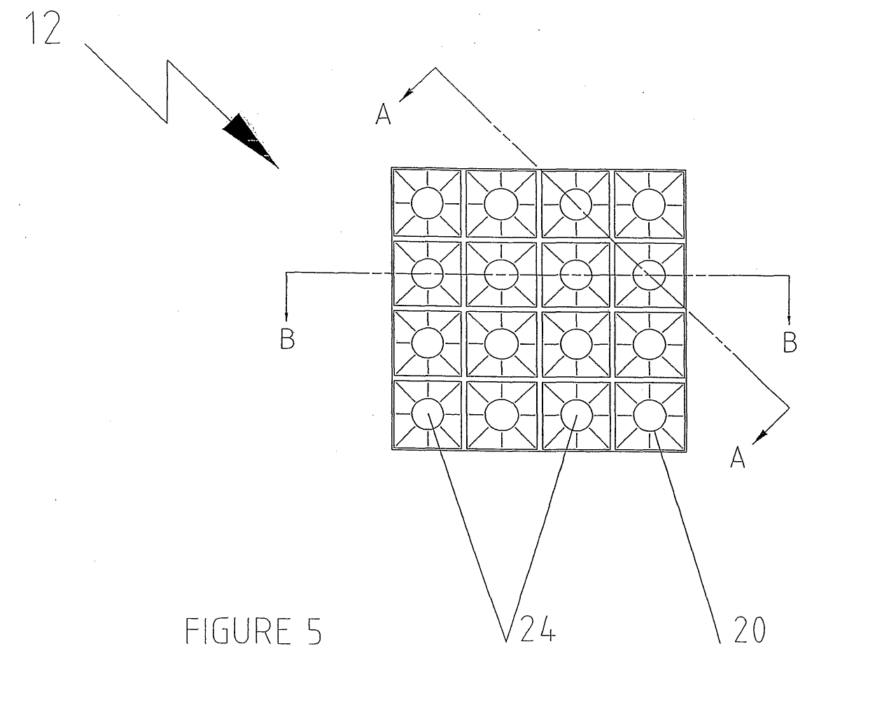

In FIG. 5, all sixteen reflector means 20 in reflector array 12 are shown, as well as holes 24, some of which are labelled.

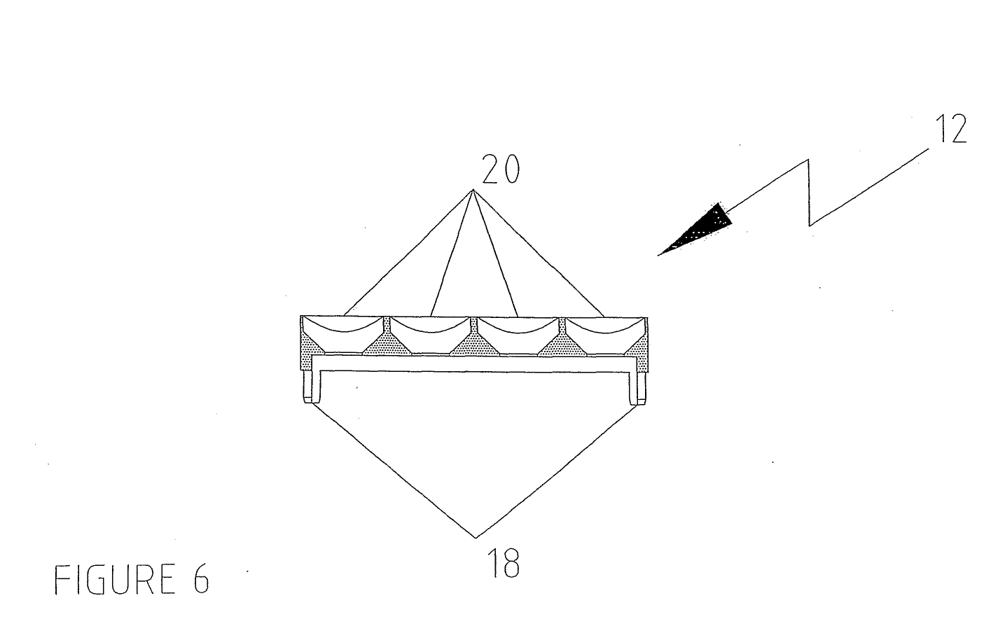

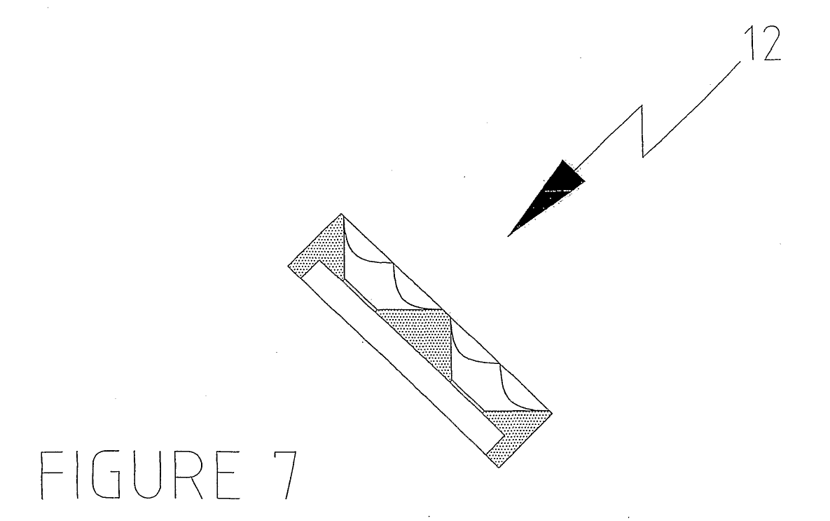

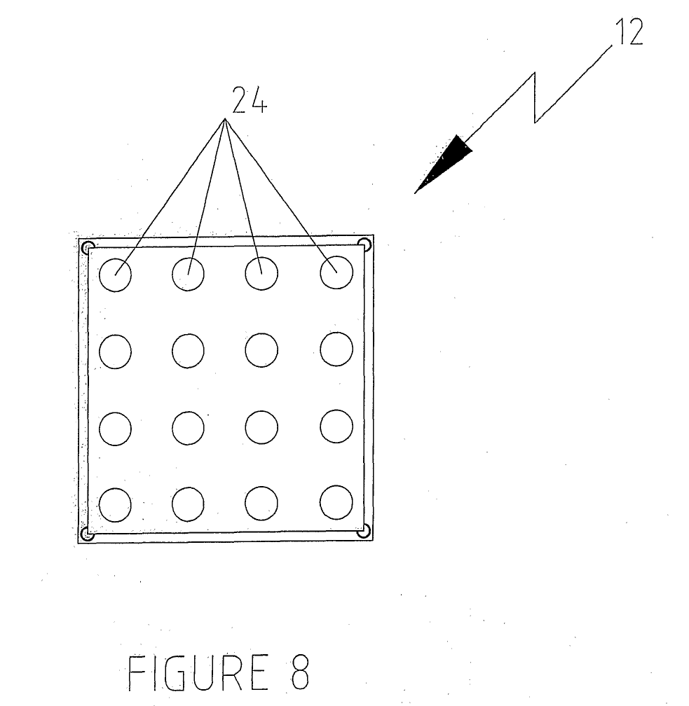

FIG. 6 shows in sectional view the shape of reflector means 20 as well as two pegs 18. A cross sectional view of reflector means 20 is shown in FIG. 7. FIG. 8, which is a bottom plan view of reflector array 12, clearly shows the location of holes 24 in reflector array 12.

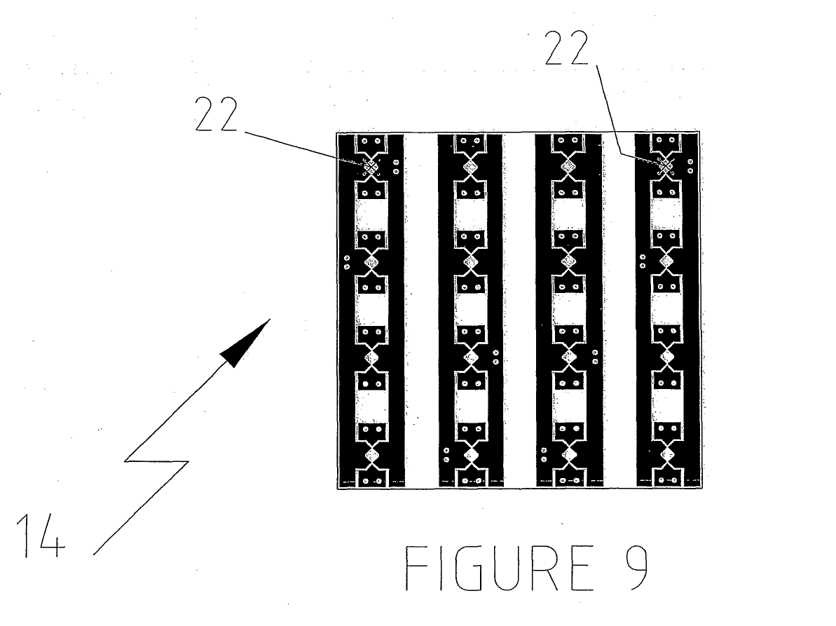

Dice carrier 14 in FIG. 9 has indicated on it the location of two of the dice sets 22.

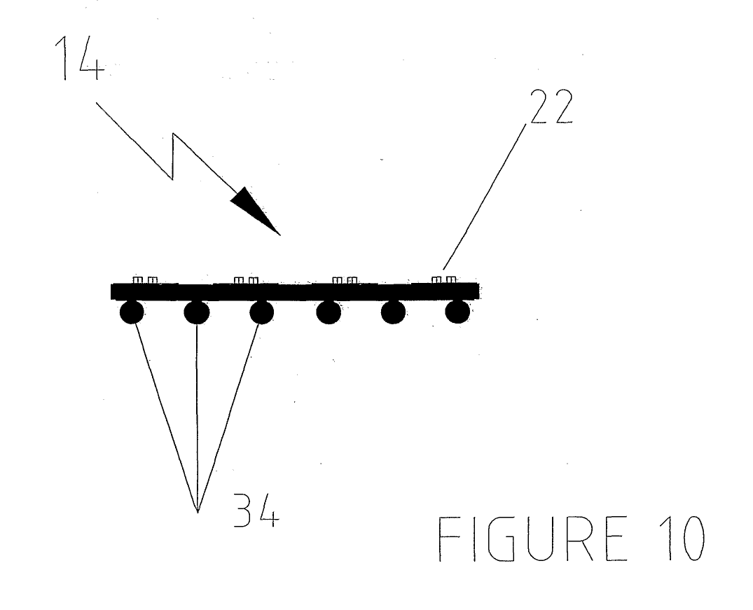

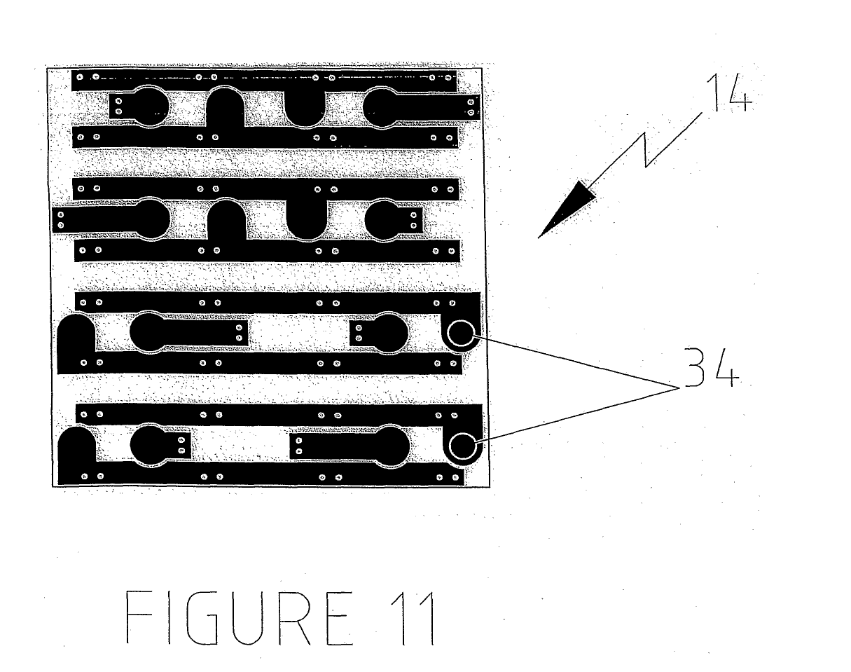

FIG. 10 shows a side elevation of dice carrier 14, with some of solder balls 34 indicated. The optimum location of solder balls 34 is shown in FIG. 11.

It will be appreciated that when reflector array 12 is assembled on dice carrier 14, pegs 18 on reflector array 12 will project towards dice carrier 14 and protect dice 22 and wire bonds connecting them to the printed circuit board from damage during assembly, when reflector array 12 is moved into position on dice carrier 14.

It is to be appreciated by one skilled in the art that variations may be made in connection with the invention as described herein without departing from the spirit and scope of the invention.

### INDUSTRIAL APPLICABILITY

The invention is capable of producing a large scale video display with smaller pixels permitting greater image quality and at the same time reducing minimum viewing distance. The method, pixel array and tile or matrix of the invention is able to accommodate changes in pixel technology and to protect wired dice from damage during assembly.

1.-20. (canceled)

21. A rectangular array of tri-color pixels, the array including:
a) a rectangular reflector array having a plurality of reflector wells; and
b) a rectangular dice carrier including a plurality of dice for each pixel;
wherein each reflector well has at its base a hole for receipt of the plurality of dice for each pixel and wherein a plurality of the pixel arrays is adapted to form a display matrix.

22. The pixel array as claimed in claim 21, which has sixteen pixels arranged in a four by four grid.

23. The pixel array of claim 21, wherein each pixel has four dice.

24. The pixel array of claim 23, wherein each pixel has one red, one blue and two green dice.

25. The pixel array of claim 21, wherein each pixel has three dice.

26. The pixel array of claim 25, wherein each pixel has one red die, one blue die and one green die

27. The pixel array of claim 21, wherein the reflector array and the reflector wells are made from polycarbonate.

28. The pixel array of claim 21, which includes a light scattering medium.

29. The pixel array of claim 21, which includes non-conductive pegs on an underside of the reflector array.

30. A tile for a large display matrix, including a plurality of pixel arrays as claimed in claim 21.

31. The tile of claim 30, wherein the large display matrix is a video display.

32. The tile of claim 30, wherein the pixel arrays are attached to a printed circuit board.

33. The tile of claim 32, wherein the pixel arrays are attached to the printed circuit board via solder balls.

34. A method for forming a rectangular array of tri-color pixels, the method including the steps of:
a) providing a rectangular reflector array having a plurality of wells, each well having at its base a hole for receipt of a plurality of dice for each pixel;
b) locating relative to the reflector array a dice carrier including the plurality of dice for each pixel, so that the plurality of dice for each pixel is located in one of the reflector well holes; and
c) providing electrical connection to each die.

35. The method of claim 34 which includes the further step:
d) attaching the carrier to a printed circuit board.
